(19) United States
(12) Patent Application Publication
(10) Pub. No.: US 2026/0092961 A1
(43) Pub. Date: Apr. 2, 2026

(54) MULTI-SPECTRAL OPTICAL DETECTOR WITH IMPROVED ANTI-FALSING

(71) Applicant: Spectronix Ltd., Sderot (IL)

(72) Inventors: Alexander FISHEL, Ashdod (IL); Dmitry HOHRYAKOV, Ashkelon (IL); Tsviel BOUHBUT, Be’er Sheva (IL); Dimitriy GRIGOROVITCH, Be'er Sheva (IL)

(21) Appl. No.: 18/901,280

(22) Filed: Sep. 30, 2024

(51) Int. Cl. G01R 31/00; G01N 21/3581; G01R 29/08; G08B 17/12

(52) U.S. Cl. CPC G01R 31/001; G01N 21/3581; G01R 29/0814; G01R 29/0885; G08B 17/12

(57) ABSTRACT

A multi-spectral optical detector includes a housing having a window. A first channel is disposed within the housing proximate the window and is sensitive to electromagnetic radiation in a first frequency range. A second channel is disposed within the housing proximate the window and is sensitive to electromagnetic radiation in a second frequency range that is different than the first frequency range. A reference channel is also disposed within the housing and is substantially insensitive to optical electromagnetic radiation. A digitizer is operably coupled to the first, second, and reference channels and is configured to provide digital indications relative to the first, second, and reference channels. A processor is coupled to the digitizer to receive the digital indications and generate a flame output signal based thereon. The processor is configured to compute a correlation between digital indications relative to the first channel and digital indications relative to the second channel and is configured to compare digital indications relative to the first and second channels with digital indication relative to the reference channel to generate an EMI indication based on the correlation and comparison.

### BACKGROUND

The process control and monitoring industry supports a wide range of process industries. Some of the process industries may employ or process materials that are highly flammable or even explosive. Examples of such industries include chemical processing facilities as well as petroleum extraction and refining. In such environments, fires and explosions are a significant hazard. In these highly volatile environments, it is useful and sometimes required to use one or more optical detectors, such as optical flame detectors, that detect any flame in the process environment so that such flame can be quickly extinguished.

### SUMMARY

A multi-spectral optical detector includes a housing having a window. A first channel is disposed within the housing proximate the window and is sensitive to electromagnetic radiation in a first frequency range. A second channel is disposed within the housing proximate the window and is sensitive to electromagnetic radiation in a second frequency range that is different than the first frequency range. A reference channel is also disposed within the housing and is substantially insensitive to optical electromagnetic radiation. A digitizer is operably coupled to the first, second, and reference channels and is configured to provide digital indications relative to the first, second, and reference channels. A processor is coupled to the digitizer to receive the digital indications and generate a flame output signal based thereon. The processor is configured to compute a correlation between digital indications relative to the first channel and digital indications relative to the second channel and is configured to compare digital indications relative to the first and second channels with digital indication relative to the reference channel to generate an EMI indication based on the correlation and comparison. A method of detecting electromagnetic interference using at least one multi-channel optical detector is also provided.

### BRIEF DESCRIPTION OF THE DRAWINGS

FIG. 1 is a system block diagram of a multi-channel optical sensor with which embodiments described herein are particularly useful.

FIG. 2 is a chart illustrating an EMI pattern and a reference channel response in accordance with an embodiment of the present invention.

FIG. 3 is a flow diagram of a computer-implemented method of detecting flame using an optical sensor with improved anti-falsing in accordance with an embodiment of the present invention.

FIG. 4 is a system block diagram of a pair of multi-channel optical sensors in accordance with another embodiment of the present invention operating in a cloud environment.

### DETAILED DESCRIPTION OF ILLUSTRATIVE EMBODIMENTS

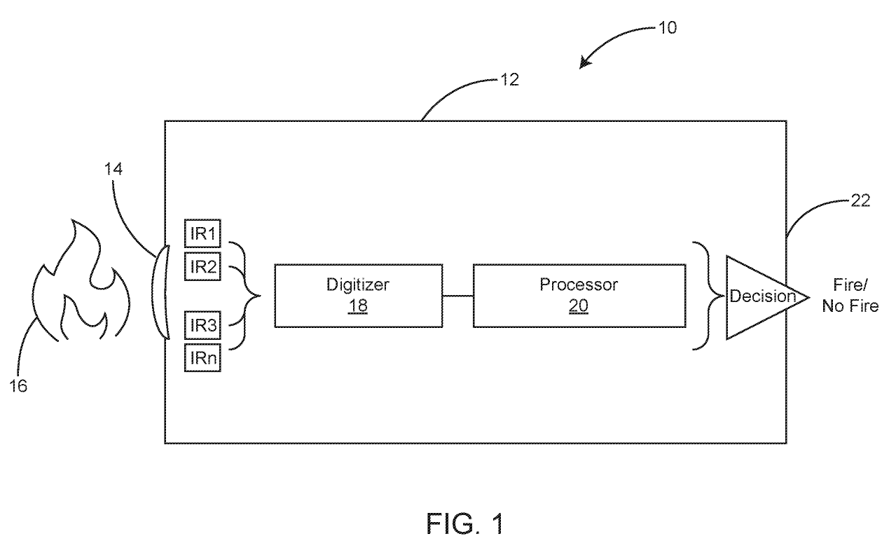

FIG. 1 is a system block diagram of a multi-channel optical sensor with which embodiments described herein are particularly useful. Multi-channel optical sensor 10, when used in the context of optical flame detection, is a device designed to detect the presence of flames by analyzing emission across multiple spectral bands or channels. Using multiple channels provides a number of advantages. First, detection accuracy is enhanced since different materials combust with different spectral characteristics. A multi-channel sensor can detect various types of fires by analyzing different parts of the electromagnetic spectrum, including ultraviolet (UV), visible light, and infrared (IR) bands. Second, the rate of false alarms is reduced by comparing the intensity of emission across several channels, these sensors can differentiate between actual flames and other emission sources that might cause false alarms, such as sunlight, artificial lights, or reflections. Third, reliability is improved since multi-channel sensors can operate effectively in a variety of environmental conditions, reducing the risk of detection failures due to factors like dust, moisture, or other atmospheric obscurants.

While embodiments described herein are applicable to multi-spectral optical sensors using any variety of wavelength detection, one embodiment will be described with respect to a plurality of individual IR sensors. Sensor 10 includes a housing 12 having a lens 14 through which flames 16 are visible. Flames 16 emit a broad spectrum of infrared radiation. The sensor 10 includes a plurality of individual IR sensors IR1, IR2, IR3, …IRₙ, where each individual sensor is sensitive to a particular band or IR wavelength. Thus, each individual sensor is essentially tuned or otherwise focused to relevant flame emission wavelengths. Each of IR sensors IR1, IR2, IR3, … IRₙ is operably coupled to digitizer 18, which includes circuitry to convert an analog signal of an individual IR sensor to a digital representation thereof. Digitizer 18 is coupled to processor 20 and is configured to provide the digital representations related to the various IR sensors to processor 20.

Processor 20 is any suitable device that is able to execute programmatic steps or functions to provide various features of sensor 10. Examples of such devices include digital signal processors, microcontrollers, field programmable gate arrays, and application specific integrated circuits. In some examples, processor 20 is a microprocessor. Digitizer 18 provides digitized representations of the IR sensor signals to processor 20 for signal processing. Processor 20 processes the digitized signals from the IR sensors and analyzes the signals from each IR sensor. Processor 20 attempts to identify specific patterns associated with flame flicker and intensity. In order to analyze the flame flicker frequency, processor 20 generally transforms the signal from time domain to frequency using a Fast Fourier Transform (FFT). By comparing the output of multiple IR sensors, processor 20 can distinguish between a flame and other IR sources like sunlight, hot machinery, or artificial lighting. The feature is achieved by analyzing the intensity and frequency response of each channel. Real flame is characterized as low frequency signals with response of 1-5Hz, and by high intensity signal at signal channels together with low intensity at reference channels. The correlation (frequency response) of the channels is expected to be high, but not full correlation, which would indicate an artificial signal. This multi-spectral analysis reduces false alarms. Processor 20 executes methods to apply such analysis to calculate the integral of the signals which will correspond to flame intensity, calculate ratios between the channels for understanding the signal channels are higher than the reference channels. The final step is to compare the frequency behavior between the different channels to measure the correlation between them.

When processor 20 confirms the presence of a flame, it generates an output 22, such as triggering an alarm and/or other suitable actions. Sensor 10 can also initiate automatic safety measures, such as shutting down equipment and/or activating fire suppression systems.

One limitation of prior art multi-channel optical detectors is due to degradation of sensor data quality while detecting flame, due to electromagnetic interference (EMI), which can be a pervasive issue in industrial environments that have many electronic devices and machinery. Traditional EMI filtering methods often struggle to differentiate between genuine sensor signals and EMI, leading to either the loss of valuable data or the inclusion of corrupted data in the analysis. Further, the EMI signal can occasionally resemble a genuine flame signal, resulting in false alarms.

Embodiments described herein generally provide a multi-spectral optical detector with improved anti-falsing. Embodiments generally utilize a number of different techniques alone or in combination to better process sensor data to reduce the level of false alarms, including those due to EMI.

In one embodiment, the sensor response is processed to analyze the correlation between multiple sensor channels to detect EMI. As described above, an EMI artificial signal will cause very high correlation between the individual sensor channels, which correlation is not possible for a real fire. When analyzing real flame, the expected correlation is higher than the detection threshold but certainly less than 100%. For example, a real flame will typically have a channel correlation in the range of 40-80%. This is caused by different responses of the flame at different wavelengths. While analyzing the EMI signal, a high correlation between channels is observed, meaning that the frequency response is very similar. This is due to the fact that EMI affects all channels in the same way and to the same degree.

In another embodiment, a reference channel is used. The reference channel employs the same IR sensor and circuitry as the sensing channels but is optically shielded from all illumination. The reference channel is not affected by flame and is expected to provide zero level of signal. During EMI, the response of the reference channel resembles the output of the channels exposed to the external world. This gives a strong indication that the signal is reaching the sensor not through the optical window, but through physical effects caused by EMI. By recognizing those signals and confirming their presence through reference channels, the system can filter out or otherwise remove or reduce the interference without discarding or altering legitimate sensor data. In some embodiments, the reference channel's signal is analyzed in the time and/or frequency domains.

Utilizing digital signal processing to provide EMI filtering addresses the distinct frequency patterns characteristic of EMI. In one embodiment, unique patterns of EMI are identified by implementing a Fourier Transform analysis on incoming signals. When analyzing real fire, an expected frequency response is 1-5hz, while EMI typically has frequency components of above 10hz, which are caused by modulation. This difference allows for the isolation of signal segments impacted by EMI. Through this recognition process, embodiments described herein are able to effectively distinguish and filter the effects of EMI on the incoming signal. This approach ensures the integrity of the signal by filtering out the interference while preserving the original data.

By conducting a comparative analysis between the reference signal and those from other channels, embodiments described herein are able to identify discrepancies attributable to EMI. This comparison allows for the precise detection and/or removal of electromagnetic interference affecting the sensor's channels. Consequently, signal integrity is enhanced by leveraging the reference channel as a baseline for identifying and mitigating EMI.

This approach provides significant advantages over existing methods, including enhanced accuracy of sensor readings in EMI-prone environments, preservation of the sensor's original sensitivity and specificity, and the ability to adapt dynamically to varying EMI signatures.

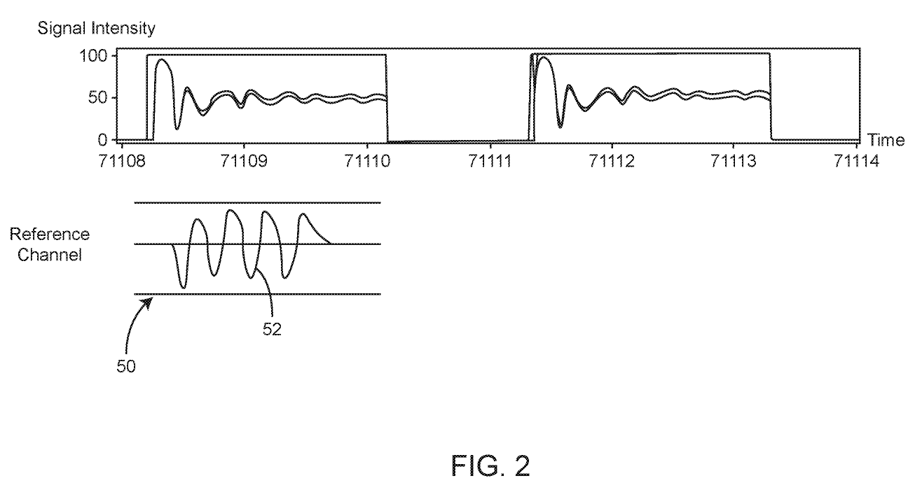

FIG. 2 is a chart illustrating an EMI pattern and a reference channel response in accordance with an embodiment of the present invention. As shown in FIG. 2, an EMI noise signal 52 is detectable on reference channel 50, while all sensor channels react to the noise signal that correlation between the various sensor channels is very high. Further, it can be seen that the frequency behavior of noise signal 52 has a specific frequency signature.

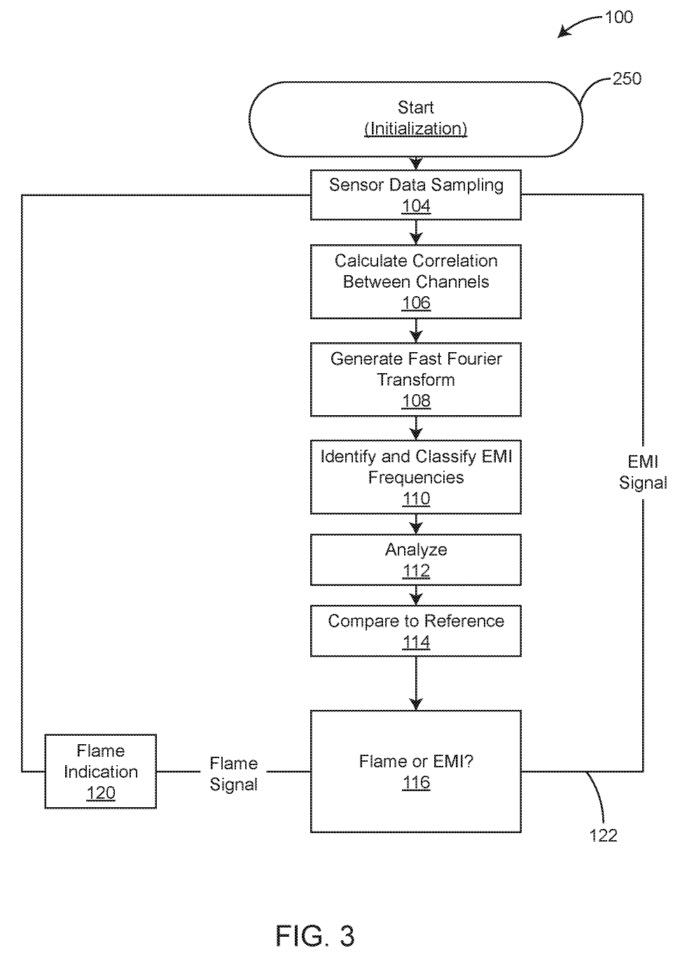

FIG. 3 is a flow diagram of a computer-implemented method of detecting flame using an optical sensor with improved anti-falsing in accordance with an embodiment of the present invention. Method 100 can be practiced on any suitable hardware including processor 20, a remote processor, such as a cloud resource, or a combination thereof. Method 100 begins at block 102. Next, at block 104, sensor data is sampled. In embodiments where method 100 is performed within a single multi-channel optical detector, the sensor data includes data from all IR sensor channels of the detector. However, in other embodiments, sensor data from multiple multichannel optical detectors may be sampled. Next, at block 106, processor 20, or a remote processor, calculates the correlation between the various channels for which data was sampled in block 104. The calculation of correlation can employ any suitable technique including, without limitation, obtaining the Pearson correlation coefficient, the Spearman correlation coefficient, and/or the Kendall correlation coefficient. Once the correlation has been calculated or while the correlation is being calculated, processor 20 or a remote processor, performs a Fast Fourier Transform on sampled data from each channel sampled during block 104. The Fast Fourier Transform is a process that computes the Discrete Fourier Transform (DFT) of a sequence, or its inverse (IDFT). Fourier analysis converts a signal from its original domain (often time or space) to a representation in the frequency domain and vice versa. In this case, the sampled data from each channel is subjected to the Fast Fourier Transform to identify frequency characteristics in the sampled data.

At block 110, processor 20, or a remote processor, identifies and/or classifies EMI frequencies from the frequency data generated by the Fast Fourier Transform of block 108. For example, frequency components that are detected that may not be indicative of flame (i.e., above 10 hertz) can be classified as indicative of EMI. Next, at block 112 processor 20, or a remote processor, performs data analytics on the correlated sensor channel data and identified/classified frequency data. This allows for data filters to be adjusted when EMI is observed in the sensor channels. The utilization of correlations between sensor channels within the device and/or with other devices together with frequency pattern characteristic distinctions and using one or more reference channels provides superior anti-falsing results. Unlike approaches that employ generic filtering across all data (hardware, optic, or software-based filters) potentially losing valuable information or failing to filter EMI effectively, embodiments described herein can utilize sophisticated processing to analyze the specific interference patterns across the different channels. This facilitates targeted removal or reduction of EMI thereby significantly reducing the likelihood of false alarms.

Next, at block 114, data analyzed at block 112 is compared to data from one or more reference channels. As set forth above, a reference channel includes the same electronic components and similar connections (e.g., circuit traces or wires) as a sensing channel. The reference channel is set as a reference channel by ensuring that no illumination can reach it. This can be done with optical shielding, mechanical design, or both. Thus, when a signal is present on the reference channel, it is, per se, interference. At block 114, the signals from the sensor channels as well as analytical data (e.g., threshold data, frequency characteristic data, etc.) is compared with the reference channel to determine whether the signals are valid flame signals or EMI. Additionally, in instances where both valid flame signals and EMI are present, comparison to the reference channel allows a determination of whether the flame signal is strong enough to generate a flame indication as indicated at block 120. If the signal is determined to be EMI, method 100 may iterate, as indicated at line 122, where control returns to block 104. However, if frequency characteristics of EMI have been identified, as indicated at block 110, those frequencies can be selectively attenuated, in the time domain, frequency domain, or both, to cause the next iteration of data sampling to be less sensitive in that frequency band.

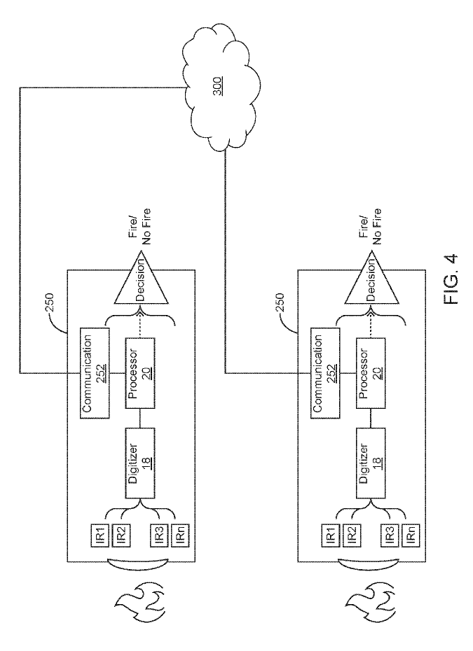

FIG. 4 is a system block diagram of a pair of multi-channel optical sensors in accordance with another embodiment of the present invention operating in a cloud computing environment. FIG. 4 is a system block diagram of a pair of multi-channel optical sensors in accordance with another embodiment of the present invention operating in a cloud environment. Each sensor 250 shown in FIG. 6 includes a communication module 252 coupled to a processor 20 and operably coupled to cloud computing system 300. Communication module 252 allows processor 20 to communicate with a remote device, such as a cloud computing system 300. Such communication can take any suitable form but is preferably wireless communication. Examples of wireless communication include, without limitation: the WirelessHART process communication protocol (IEC62591); a cellular communication protocol such as GPRS, UMTS, CDMA2000, LTE, LTE-M, NB-IOT, WiMax, 5G NR.; a WiFi standard, such as IEEE 802.11 b/g/n/a/ac/ax/be; and LoRaWAN protocol (ITU-T Y.4480). Leveraging cloud-based analytics, such as that provided by cloud computing resource 300, enables advanced data analysis, predictive maintenance, and remote monitoring capabilities. In one example, cloud computing resource 300 can execute method 100 and since resource 300 is coupled to a plurality of sensors 250 may be able to identify EMI better than a single multi-channel optical sensor. Further, if the positions of sensors 250 are known, cloud resource 300 may even be able to localize one or more sources of EMI for remediation.

Although the present invention has been described with reference to preferred embodiments, workers skilled in the art will recognize that changes may be made in form and detail without departing from the spirit and scope of the invention.

WHAT IS CLAIMED IS:

1. A multi-spectral optical detector comprising:
a housing having a window;
a first channel disposed within the housing proximate the window and being sensitive to electromagnetic radiation in a first frequency range;
a second channel disposed within the housing proximate the window and being sensitive to electromagnetic radiation in a second frequency range that is different than the first frequency range;
a reference channel disposed within the housing and being substantially insensitive to optical electromagnetic radiation;
a digitizer operably coupled to the first, second, and reference channels, the digitizer being configured to provide digital indications relative to the first, second, and reference channels;
a processor coupled to the digitizer to receive the digital indications and generate a flame output signal based thereon; and
wherein the processor is configured to compute a correlation between digital indications relative to the first channel and digital indications relative to the second channel, and wherein the processor is further configured to compare digital indications relative to the first and second channels with digital indication relative to the reference channel to generate an EMI indication based on the correlation and comparison.

2. The multi-spectral optical detector of claim 1, and further comprising at least one additional channel disposed within the housing proximate the window and being sensitive to electromagnetic radiation in at least one additional frequency range that is different than the first frequency range and the second frequency range.

3. The multi-spectral optical detector of claim 1, wherein the processor is configured to determine whether the computed correlation is higher than a flame detection threshold but lower than an electromagnetic interference threshold and selectively provide a flame output signal based on the determination.

4. The multi-spectral optical detector of claim 1, wherein the processor is configured to generate a Fast Fourier Transform of digital indications relative to each of the first and second channels.

5. The multi-spectral optical detector of claim 4, wherein the processor is configured to identify frequency characteristics of electromagnetic interference in the Fast Fourier Transform data.

6. The multi-spectral optical detector of claim 5, wherein the processor is configured to generate an electromagnetic interference output based on identification or at least one frequency characteristic that is indicative of electromagnetic interference.

7. The multi-spectral optical detector of claim 6, wherein the at least one frequency characteristic includes frequency greater than 10 hertz.

8. The multi-spectral optical detector of claim 6, wherein the processor is configured to attenuate sensor channel signals based on the identified at least one frequency characteristic indicative of electromagnetic interference.

9. The multi-spectral optical detector of claim 5, wherein the processor is configured to recognize a pattern in the digital indications relative to the reference channel.

10. A method of detecting electromagnetic interference using at least one a multi-channel optical detector, the method comprising:
sampling data from a plurality of sensing channels of a first multi-channel optical detector;
sampling data from a reference channel of the first multi-channel optical detector;
calculating a correlation between the plurality of sensor channels;
generating a Fast Fourier Transform information for data relative to each sensor channel;
identifying at least one EMI frequency in the Fast Fourier Transform;
analyzing the correlation and identified EMI frequency and comparing the correlation to reference data to determine whether data sampled from the sensing channels is indicative of a flame or electromagnetic interference; and
selectively providing a flame output based on the determination.

11. The method of claim 10, wherein calculating the correlation between the plurality of sensor channels is performed by a processor of the first multi-channel optical detector.

12. The method of claim 10, wherein analyzing the correlation includes comparing the correlation to a range having a lower limit and an upper limit.

13. The method of claim 12, wherein a correlation above the upper limit is indicative of electromagnetic interference.

14. The method of claim 10, wherein the processor is configured to calculate a correlation between the sensing channels and the reference channel.

15. The method of claim 10, wherein analyzing the correlation and identifying at least one EMI frequency is performed by a remote device.

16. The method of claim 10, wherein the at least one multi-channel optical detector includes a plurality of multi-channel optical detectors.

17. The method of claim 16, wherein each of the plurality of multi-channel optical detectors is configured to communicate with a cloud computing resource.

18. The method of claim 17, wherein the cloud computing resource is configured to perform at least one of:
calculating the correlation between the plurality of sensor channels;
generating the Fast Fourier Transform information for data relative to each sensor channel;
identifying at least one EMI frequency in the Fast Fourier Transform;
analyzing the correlation and identified EMI frequency and comparing the correlation to reference data to determine whether data sampled from the sensing channels is indicative of a flame or electromagnetic interference; and
selecting providing a flame output based on the determination.
